(19) United States
(12) Patent Application Publication
(10) Pub. No.: US 2022/0362958 A1
(43) Pub. Date: Nov. 17, 2022

(54) DICING DEVICE, AND BLADE HEIGHT CORRECTION METHOD AND WORKPIECE PROCESSING METHOD FOR DICING DEVICE

(71) Applicant: Tokyo Seimitsu Co., Ltd., Tokyo (JP)

(72) Inventors: Marina EKI, Tokyo (JP); Shiori SAITO, Tokyo (JP)

(73) Assignee: Tokyo Seimitsu Co., Ltd., Tokyo (JP)

(21) Appl. No.: 17/876,644

(22) Filed: Jul. 29, 2022

Related U.S. Application Data
(63) Continuation of application No. PCT/JP2021/001757, filed on Jan. 20, 2021.

(30) Foreign Application Priority Data
Feb. 6, 2020 (JP) 2020-018878

(51) Int. Cl. B26D 3/22; B26D 1/18; B26D 5/00

(52) U.S. Cl. CPC B26D 3/225; B26D 1/18; B26D 5/005

(57) ABSTRACT

A dicing device includes: a workpiece table; a cutting unit including a blade and a spindle; an XY-direction drive unit; a Z-direction drive unit; a first measuring instrument for measuring a Z-direction position of a surface of a workpiece held on a holding surface of the workpiece table; a second measuring instrument for measuring a Z-direction displacement of the holding surface; a correction amount calculation unit for calculating a correction amount for the Z-direction position of the cutting unit based on a table displacement map showing the Z-direction displacement at each position on the holding surface, the Z-direction displacement having been measured in advance by the second measuring instrument and based on the Z-direction position of the surface of the workpiece, measured by the first measuring instrument; and a control unit for controlling, when the workpiece is cut by a blade, the Z-direction drive unit based on the correction amount.

### CROSS-REFERENCE TO RELATED APPLICATIONS

The present application is a Continuation of PCT International Application No. PCT/JP2021/001757 filed on Jan. 20, 2021 claiming priority under 35 U.S.C. § 119(a) to Japanese Patent Application No. 2020-018878 filed on Feb. 6, 2020. Each of the above applications is hereby expressly incorporated by reference, in their entirety, into the present application.

### BACKGROUND OF THE INVENTION

### 1. Field of the Invention

The present invention relates to a dicing device. In particular, the present invention relates to a dicing device that divides a workpiece such as a wafer, on which semiconductor devices or electronic components are formed, into individual chips, and a blade height correction method and a workpiece processing method for the dicing device.

### 2. Description of the Related Art

A dicing device that divides a workpiece such as a wafer, on which semiconductor devices or electronic components are formed, into individual chips includes: a blade that is rotated at high speed by a spindle; a workpiece table that sucks and holds the workpiece; and X, Y, Z and θ drive units that change the relative position of the workpiece table with the blade. This dicing device cuts the workpiece with the blade while relatively moving the blade and the workpiece by the drive units, and thereby performs dicing process (cutting process).

In a dicing device, it is an important factor to make the cutting amount of the blade identical to the set value. To make the cutting amount of the blade identical to the set value, it is necessary to repeatedly position a Z-axis, which is the cutting direction to the workpiece, with high accuracy.

Patent Literature 1: Japanese Patent Application Laid-Open No. 2018-027601

### SUMMARY OF THE INVENTION

If there are variations in the thickness of a workpiece, an adhesive layer such as a tape or a base material that fixes the workpiece, or a height of a table that holds the workpiece, the workpiece or the adhesive layer may be cut too deep, or may not be cut, when the workpiece or the adhesive layer is cut (for example, half-cutting). Therefore, it is necessary to control the height of the blade in real time during cutting of the workpiece to control the depth of cut and the depth of uncut portion with high accuracy.

Patent Literature 1 discloses a cutting method of controlling a cutting depth of a cutting blade with respect to a workpiece. In Patent Literature 1, heights (Z) of a holding surface of a chuck table provided in a cutting device are measured at a plurality of coordinates (X, Y), and the relationship between the coordinates (X, Y) and the respective heights (Z) is stored as holding surface information. Next, thicknesses (t) of a workpiece are measured at a plurality of coordinates (x, y), and the relationship between the coordinates (x, y) and the respective thicknesses (t) is stored as thickness information. Then, the height of the upper surface of the workpiece is calculated at a given coordinate (X, Y) from the position information, the holding surface information, and the thickness information, and the cutting blade is fed based on the height of the upper surface of the workpiece calculated in the calculation step, so that a groove with a desired depth is formed in the workpiece.

In the method described in Patent Literature 1, when a coordinate (X, Y) of the holding surface information is not the same as a coordinate (x, y) of the thickness information, for example, a height of the surface of the workpiece is calculated using the holding surface information (height (Z)) at a given coordinate and the thickness information (thickness (t)) at another coordinate closest to the former coordinate. In this case, it is difficult to control the height of the blade in real time with high accuracy.

Further, the method described in Patent Literature 1 uses a thickness measuring device having a flatly formed holding surface to measure the thickness of the workpiece with high accuracy in the step of storing the thickness information. The thickness measuring device, which is provided inside or outside the cutting device, has a problem that makes the process complicated so that the device for carrying out the method is expensive.

The present invention has been made in view of such circumstances, and an object of the present invention is to provide a dicing device with a simple configuration capable of controlling a height of a blade in real time with high accuracy, and a blade height correction method and a workpiece processing method for a dicing device.

To solve the above problems, a dicing device according to a first aspect of the present invention includes: a workpiece table for holding a workpiece on a holding surface parallel to an XY plane; at least one cutting unit each including: a blade for cutting the workpiece held on the workpiece table; and a spindle for rotating the blade around a rotation axis parallel to the XY plane; an XY-direction drive unit for moving the cutting unit and the workpiece table relatively in a direction parallel to the XY plane; a Z-direction drive unit for moving the cutting unit in a Z-direction perpendicular to the XY plane; a first measuring instrument, movably attached together with the cutting unit, for measuring a Z-direction position of a surface of the workpiece held on the holding surface of the workpiece table; a second measuring instrument for measuring a Z-direction displacement of the holding surface of the workpiece table; a correction amount calculation unit for calculating a correction amount for a Z-direction position of the cutting unit, based on a table displacement map showing the Z-direction displacement at each position on the holding surface of the workpiece table and based on the Z-direction position of the surface of the workpiece, the Z-direction displacement having been measured in advance by the second measuring instrument, the Z-direction position being measured by the first measuring instrument; and a control unit for controlling, when the workpiece is cut by the blade, the Z-direction drive unit based on the correction amount.

A dicing device according to a second aspect of the present invention is configured such that, in the first aspect, the at least one cutting unit includes two cutting units, the first measuring instrument is attached to one of the two cutting units, and the second measuring instruments are each arranged at the same Z-direction position as a lower end of the blade of each of the two cutting units.

A dicing device according to a third aspect of the present invention is configured such that, in the first or second aspect, the correction amount calculation unit calculates a workpiece thickness map showing thicknesses of the workpiece at individual positions on the workpiece based on the table displacement map showing the Z-direction displacement at each position on the holding surface of the workpiece table and based on the Z-direction position of the surface of the workpiece, the Z-direction displacement having been measured in advance by the second measuring instrument, the Z-direction position being measured by the first measuring instrument, and calculates the correction amount for the Z-direction position of the cutting unit based on the table displacement map and the workpiece thickness map.

A dicing device according to a fourth aspect of the present invention is configured such that, in any of the first to third aspects, the first measuring instrument includes an air micrometer.

A dicing device according to a fifth aspect of the present invention is configured such that, in any of the first to fourth aspects, the second measuring instrument includes a differential transformer.

A sixth aspect of the present invention is a blade height correction method for a dicing device including a workpiece table for holding a workpiece on a holding surface parallel to an XY plane, at least one cutting unit, a first measuring instrument, and a second measuring instrument, the cutting unit including a blade for cutting the workpiece, the cutting unit being movable in a Z-direction perpendicular to the XY plane, the blade height correction method including: a step of acquiring a table displacement map showing a Z-direction displacement at each position on the holding surface of the workpiece table, the Z-direction displacement having been measured by the second measuring instrument; a step of measuring, by the first measuring instrument, a Z-direction position of a surface of the workpiece held on the holding surface of the workpiece table; and a correction amount calculating step of calculating a correction amount for a Z-direction position of the cutting unit based on the table displacement map and the Z-direction position of the surface of the workpiece, the Z-direction position being measured by the first measuring instrument.

A blade height correction method according to a seventh aspect of the present invention is configured such that, in the correction amount calculating step in the sixth aspect, a workpiece thickness map showing thicknesses of the workpiece at individual positions on the workpiece is calculated based on the table displacement map showing Z-direction displacement at each position on the holding surface of the workpiece table and based on the Z-direction position of the surface of the workpiece, the Z-direction displacement having been measured in advance by the second measuring instrument, the Z-direction position being measured by the first measuring instrument; and the correction amount for the Z-direction position of the cutting unit is calculated based on the table displacement map and the workpiece thickness map.

A workpiece processing method according to an eighth aspect of the present invention includes a step of controlling, based on the correction amount calculated by the method according to the sixth or seventh aspect, the Z-direction position of the cutting unit when the workpiece is cut by the blade.

The present invention makes it possible to control the Z-direction height of the blade in real time with high accuracy if the table, dicing tape, workpiece, and base plate each have a displacement component in the Z-direction.

### BRIEF DESCRIPTION OF THE DRAWINGS

FIG. 1 is a perspective view illustrating a dicing device according to an embodiment of the present invention;

FIG. 2 is a perspective view illustrating a state in which a second measuring instrument is attached to the dicing device;

FIG. 3 is a block diagram illustrating a control system of the dicing device according to the embodiment of the present invention;

FIG. 4 is a cross-sectional view illustrating an example of half-cutting a dicing tape to which a workpiece is pasted;

FIG. 5 is a diagram schematically illustrating a procedure of calculating a correction amount for a height of a spindle;

FIG. 6 is a flowchart illustrating a procedure of calculating correction data according to a first embodiment of the present invention;

FIG. 7 is a flowchart illustrating a blade height control method in dicing; and

FIG. 8 is a flowchart illustrating a blade height control method according to a first modification.

### DESCRIPTION OF THE PREFERRED EMBODIMENTS

The following describes embodiments of a dicing device, and a blade height correction method and a workpiece processing method for a dicing device according to the present invention with reference to the accompanying drawings.

### Dicing Device

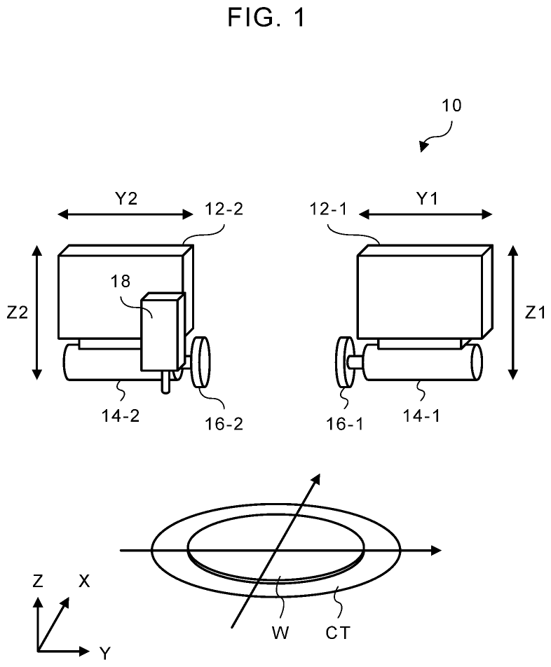

FIG. 1 is a perspective view illustrating a dicing device according to an embodiment of the present invention. The following description uses a three-dimensional orthogonal coordinate system.

As illustrated in FIG. 1, a dicing device 10 according to the present embodiment includes: a cutting unit 12 (a first cutting unit 12-1 and a second cutting unit 12-2) for dicing process of a workpiece (wafer) W; and a workpiece table (a cutting table, hereinafter referred to as a table) CT. In the following description, configurations common to the two cutting units 12-1 and 12-2 are described without the branch numbers.

The table CT has a holding surface parallel to an XY plane, and sucks and holds the workpiece W on this holding surface. The workpiece W is pasted to a frame F via a dicing tape T whose surface is formed with an adhesive layer of an adhesive, and is sucked and held by the table CT. Here, the frame F to which the dicing tape T is pasted is held by frame holding means (not illustrated) disposed on the table CT. Note that a transfer manner that does not use the frame F may be used.

The table CT is attached to a θ table (not illustrated), and the θ table can be rotated in a θ direction (around a rotation axis centered on a Z axis) by a rotation drive unit including a motor and the like. The θ table is placed on an X table (not illustrated). The X table can be moved in the X-direction by an X drive unit including a motor, a ball screw, and the like.

The first cutting unit 12-1 and the second cutting unit 12-2 are respectively attached to a Z1 table and a Z2 table (not illustrated). The Z1 table and the Z2 table can respectively be moved in a Z1 direction and a Z2 direction by a Z drive unit including a motor, a ball screw, and the like. A Y1 attached to the Z1 table, and A Y2 table attached to the Z2 table. The Y1 table and the Y2 table can respectively be moved in a Y1 direction and Y2 direction by a Y drive unit including a motor, a ball screw, and the like.

In the present embodiment, the X drive unit, the Y drive unit, and the Z drive unit each use a configuration including a motor, a ball screw, and the like, but the present invention is not limited thereto. The X drive unit, the Y drive unit, and the Z drive unit can use, for example, a mechanism for reciprocating linear motion such as a rack and pinion mechanism.

As illustrated in FIG. 1, the first cutting unit 12-1 includes a first spindle 14-1 and a first blade 16-1. The second cutting unit 12-2 includes a second spindle 14-2 and a second blade 16-2. The first blade 16-1 and the second blade 16-2 are, for example, disk-shaped cutting blades. Instead, the first blade 16-1 and the second blade 16-2 may be, for example, an electrodeposition blade with diamond abrasive grains or CBN (Cubic Boron Nitride) abrasive grains electrodeposited with nickel, a resin blade bonded with a resin, or the like. The first blade 16-1 and the second blade 16-2 can be replaced according to conditions, such as the type, size, and processing manner, of the workpiece W to be processed.

The first blade 16-1 and the second blade 16-2 are respectively attached to the ends of the first spindle 14-1 and the second spindle 14-2. The first spindle 14-1 and the second spindle 14-2 each include a high-frequency motor. The high-frequency motors rotate the first blade 16-1 and the second blade 16-2 at high speed.

With this configuration, the first blade 16-1 and the second blade 16-2 are fed for index respectively in the Y1 and Y2 directions, and are fed for cut respectively in the Z1 and Z2 directions. Further, the table CT is rotated in the θ direction and fed for cut in the X-direction.

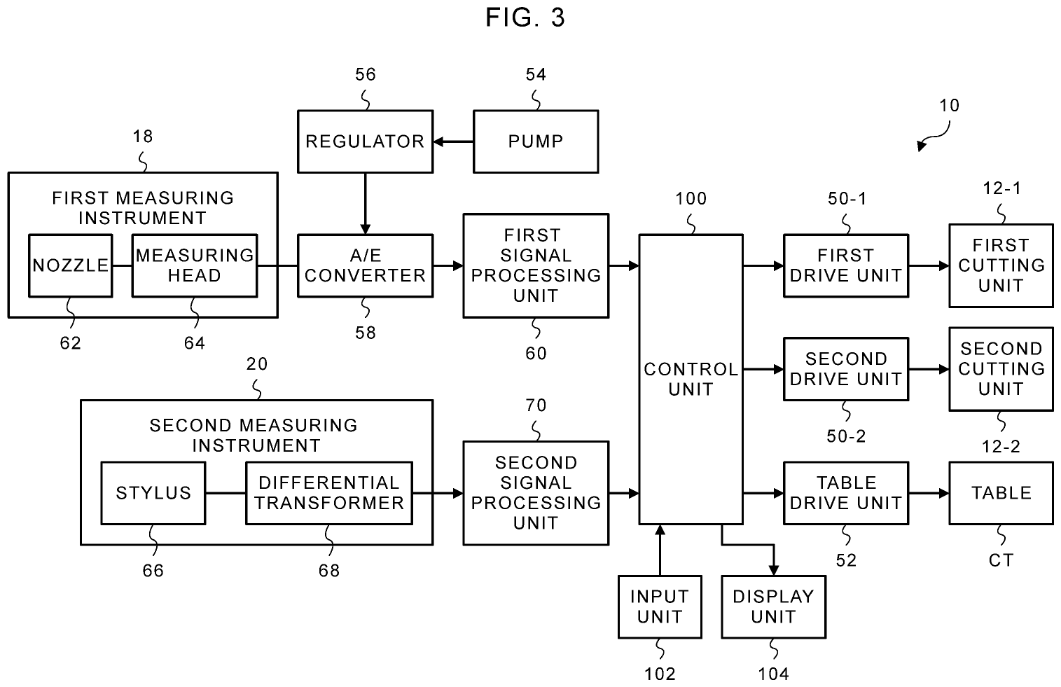

A first measuring instrument 18 is attached to the lateral surface of the second cutting unit 12-2. The first measuring instrument 18 is, for example, an air micrometer (see FIG. 3). The first measuring instrument 18 measures a displacement of the surface of the table CT in the Z coordinate, and a displacement of the workpiece W held on the table CT in the Z coordinate. The first measuring instrument 18 can move in the Y2 and Z2 directions together with the second cutting unit 12-2.

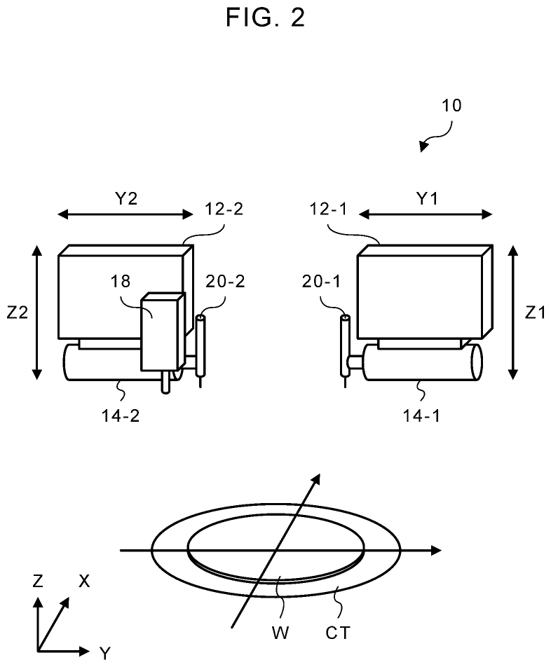

A second measuring instrument 20-1 can be attached to the first cutting unit 12-1, and a second measuring instrument 20-2 can be attached to the second cutting unit 12-2. The second measuring instruments 20-1 and 20-2 are, for example, contact type displacement sensors (see FIG. 3), and measure displacements of the surface of the table CT in the Z coordinate. As illustrated in FIG. 2, the second measuring instruments 20-1 and 20-2 are respectively attached after the first blade 16-1 and the second blade 16-2 are removed. The XY-direction positions of the ends of the styluses of the second measuring instruments 20-1 and 20-2 are the same as the XY-positions of the first blade 16-1 and the second blade 16-2, respectively. The second measuring instrument 20-1 can move in the Y1 and Z1 directions together with the first cutting unit 12-1. The second measuring instrument 20-2 can move in the Y2 and Z2 directions together with the second cutting unit 12-2.

In the example illustrated in FIG. 1, the number of table CTs is one, but the number of table CTs may be two or more. Further, the number of cutting units 12 may be one.

Next, a control system of the dicing device 10 will be described with reference to FIG. 3. FIG. 3 is a block diagram illustrating a control system of the dicing device according to the embodiment of the present invention.

As illustrated in FIG. 3, the control system of the dicing device 10 according to the present embodiment includes a control unit 100, an input unit 102, and a display unit 104. The control system of the dicing device 10 can be configured by a general-purpose computer such as a personal computer or a microcomputer.

The control unit 100 includes a CPU (Central Processing Unit), a ROM (Read Only Memory), a RAM (Random Access Memory), a storage device (for example, a hard disk), and the like. In the control unit 100, various programs such as a control program stored in the ROM are expanded in the RAM, and the program expanded in the RAM is executed by the CPU to cause each unit of the dicing device 10 to function.

The input unit 102 includes an operation member (for example, a keyboard, a pointing device) for receiving an operation input from a user.

The display unit 104 is a device that displays a GUI (Graphical User Interface) or the like for operating the dicing device 10, and includes, for example, a liquid crystal display.

A first drive unit 50-1 includes a motor for moving the first spindle 14-1 along the processing axes (Y1 axis and Z1 axis). A second drive unit 50-2 includes a motor for moving the second spindle 14-2 along the processing axes (Y2 axis and Z2 axis).

A table drive unit 52 includes: a motor for rotating the θ table, to which the table CT is attached, in the θ direction; and an X drive unit including a motor for moving the table CT in the X-direction, a ball screw, and the like.

Note that the spindle 14 is moved in the YZ-direction in the present embodiment, but the table CT, or both the spindle 14 and the table CT may be moved in the YZ-direction.

The control unit 100 controls the first drive unit 50-1, the second drive unit 50-2, and the table drive unit 52, to adjust the relative positions of the workpiece W held on the table CT, and the first spindle 14-1 and the second spindle 14-2. Here, the first drive unit 50-1, the second drive unit 50-2, and the table drive unit 52 function as the XY-direction drive unit and the Z-direction drive unit.

As illustrated in FIG. 3, the dicing device 10 includes a first measuring instrument 18, a pump 54, a regulator 56, an A/E (Air/Electronic) converter 58, and a first signal processing unit 60. The first measuring instrument 18 is an air micrometer, and includes a nozzle 62 and a measuring head 64.

The air micrometer 18 adjusts the compressed air supplied from the pump 54 to a constant pressure by the regulator 56. Then, the air micrometer 18 jets out the compressed air onto the surface of the workpiece W from the nozzle 62 of the measuring head 64 via a throttle (not illustrated) installed inside the A/E converter 58.

The A/E converter 58 converts a minute change in the air flow rate (pressure) between the nozzle 62 and the throttle into an electric signal by built-in bellows and a built-in differential transformer, and outputs the electric signal to the first signal processing unit 60.

The first signal processing unit 60 amplifies the electric signal input from the A/E converter 58, calculate the air flow rate based on the amplified electric signal, and calculates the distance to the workpiece W based on the calculated air flow rate. In other words, the first signal processing unit 60 calculates the distance between the lower end portion (−Z side end portion) of the first measuring instrument 18 and the workpiece W, based on the flow rate of air flowing out from the gap between the nozzle 62 and the workpiece W or the pressure change caused by the change in the flow rate.

In the present embodiment, a flow rate type air micrometer is used, but the present invention is not limited to this. For example, an air micrometer of other measurement principles such as a back pressure type, a vacuum type, and a flow velocity type may be used.

As illustrated in FIG. 3, the dicing device 10 includes a second measuring instrument 20 and a second signal processing unit 70. The second measuring instrument 20 is a contact type displacement sensor, and includes a stylus 66 and a differential transformer 68.

The stylus (contact finger) 66 is held so as to be movable in the Z-direction, is in contact with the surface of the workpiece W, and is displaced according to the shape of the surface of the workpiece W.

The differential transformer 68 includes a coil and a core that operates in the coil according to the displacement of the stylus 66, converts the displacement of the stylus 66 into an electric signal, and outputs the electric signal to the second signal processing unit 70.

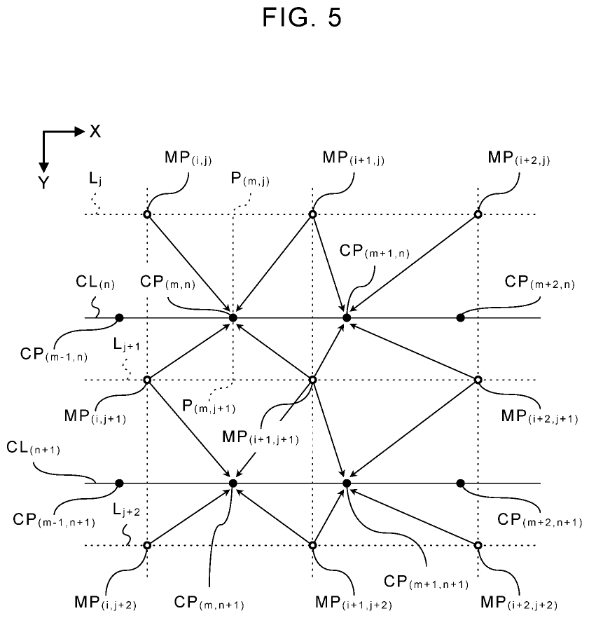

The second signal processing unit 70 calculates the displacement of the stylus 66 based on the electric signal input from the differential transformer 68. Thereby, the Z coordinate at each measurement point MP_{(i, j)} on the table CT (see FIG. 5) can be calculated.

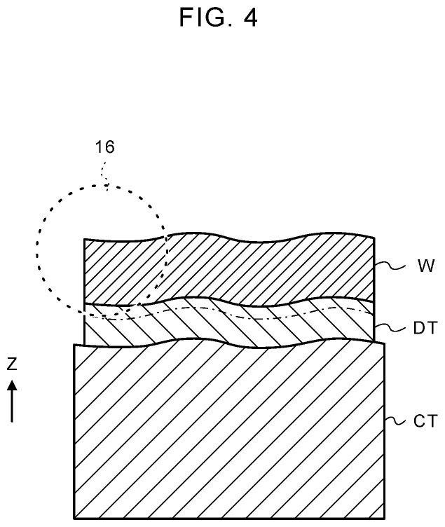

The control unit 100 measures the displacement (unevenness) of the surface of the table CT by the second measuring instrument 20, and creates a table displacement map showing the Z-direction displacement at each measurement point MP_{(i, j)} in the XY-direction. Then, as illustrated in FIG. 4, when dicing is performed on the workpiece W held in the table CT, the control unit 100 controls the height of the first cutting unit 12-1 and the second cutting unit 12-2, based on the table displacement map. FIG. 4 illustrates an example of half-cutting the dicing tape DT to which the workpiece W is pasted.

Note that the same height control can also be applied for a configuration such that the base plate is sandwiched between the table CT and the dicing tape DT.

### Height Control

The following describes the height control of the spindle 14 (blade 16) according to the present embodiment. FIG. 5 is a diagram schematically illustrating a procedure of calculating a correction amount for the height of the spindle.

First, the surface (upper surface) of the table CT is measured using the second measuring instrument 20. As illustrated in FIG. 5, the second measuring instrument 20 measures the Z coordinate at each measurement point MP_{(i, J)} arranged in a grid pattern on the table CT, and obtains the displacement amount in the Z-direction at the lower end position of the blade 16. The displacement amount in the Z-direction at each measurement point MP_{(i, j)} is stored in the control unit 100 as data of the table displacement map.

In the following description, the table displacement map created based on the measurement results of the second measuring instrument 20-1 of the first cutting unit 12-1 is referred to as z1_smap; the table displacement map created based on the measurement results of the second measuring instrument 20-2 of the second cutting unit 12-2 is referred to as z2_smap.

Here, the displacement amounts Z in the Z-direction in the table displacement maps (z1_smap and z2_smap) respectively include Z-direction undulation components of the mounting postures of the blades 16-1 and 16-2 in the XY-direction. In other words, the displacement amounts Z in the Z-direction in the table displacement maps (z1_smap and z2_smap) include the components of the straightness errors at the lower end positions of the blades 16 in the X and Y-directions, and the components of errors from the plane of the table CT.

Next, the workpiece W to be cut is held on the surface of the table CT. Then, the surface of the workpiece W held on the surface of the table CT is measured using the first measuring instrument (air micrometer) 18. In the measurement of workpiece W, similarly to table CT measurement, the first measuring instrument measures the Z coordinates at measurement points MP_{(i, j)}, and obtains the displacement amounts in the Z-direction at the lower end position of the blade 16. Note that, in the present embodiment, the measurement points MP_{(i, j)} in a workpiece thickness map (amm_map) obtained from the measurement results of the first measuring instrument 18 are the same as those in the table displacement maps (z1_smap and z2_smap), for simplicity. However, the measurement points do not necessarily need to be the same in the maps. When the measurement points in the thickness map (amm_map) are not the same as those in the table displacement maps (z1_smap and z2_smap), an interpolation operation (e.g., two-dimensional interpolation, see FIG. 4) can be used to obtain any displacement amount in the Z-direction.

Here, the displacement amount Z in the Z-direction in the workpiece thickness map (amm_map) includes Z-direction undulation components of the mounting posture of the first measuring instrument 18 in the XY-direction. In other words, the displacement amount Z includes the components of the straightness errors at the lower end position of the first measuring instrument 18 in the X-direction and the Y-direction, and the components of the errors from the plane of the table CT.

The control unit 100 uses the table displacement maps to cancel out the Z-direction undulation components from the displacement amount in the Z-direction at each measurement point MP_{(i, j)}, and thereby obtains the thickness of the workpiece W. The thickness of the workpiece W at each measurement point MP_{(i, j)} is stored in the control unit 100 as data of the workpiece thickness map amm_map.

Next, the control unit 100 calculates the correction amount for the height of the spindle 14 for each measurement point MP_{(i, j)}. Here, the control unit 100 functions as a correction amount calculation unit. The correction amount SP1 for the first spindle 14-1 and the correction amount SP2 for the second spindle 14-2 are respectively calculated by the following expressions.

SP1=(measurement result by the first measuring instrument 18−amm_map)+z1_smap (1)

SP2=(measurement result by the first measuring instrument 18−amm_map)+z2_smap (2)

The correction data including the correction amounts SP1 and SP2 at each measurement point MP(i, j) are stored in the storage device of the control unit 100.

In the example illustrated in FIG. 5, the measurement points MP_{(i, j)} are evenly arranged in a grid pattern on the table CT. Typically, a straight line Lⱼ passing through these measurement points MP_{(i, j)} does not overlap with the scheduled division line CL₍ₙ₎.

Therefore, in the present embodiment, the correction amount Z_{(m, n)} at the correction point CP_{(m, n)} on the scheduled division line CL₍ₙ₎ is calculated using the correction amount Z_{(i, j)} of the correction data at the measurement points MP_{(i, j)} around the correction point CP_{(m, n)}. Specifically, the correction amount Z_{(m, n)} at the correction point CP_{(m, n)} on the scheduled division line CL₍ₙ₎ is calculated using the correction amount at four measurement points MP_{(i, j)}, MP_{(i+1, j)}, MP_{(i, j+1)} and MP_{(i+1, j+1)} surrounding the correction point CP_{(m, n)} in a grid pattern.

Here, the procedure of two-dimensional linear interpolation is described. In the following description, it is assumed that the straight lines Lⱼ and Lⱼ₊₁ in the table displacement map are parallel to the X axis. The coordinate and correction amount at the correction point CP_{(m, n)} on the scheduled division line CL₍ₙ₎ are (Xₘ, Yₙ, Z_{(m, n)}). The coordinates and correction amounts of points MP_{(i, j)}, MP_{(i+1, j)}, MP_{(i, j+1)} and MP_{(i+1, j+1)} in the table displacement map are respectively (Xᵢ, Yⱼ, Z_{(i, j)}), (Xᵢ₊₁, Yⱼ, Z_{(i+1, j)}), (Xᵢ, Yⱼ₊₁, Z_{(i, j+1)}) and (Xᵢ₊₁, Yⱼ₊₁, Z_{(i+1, j+1)}).

In the two-dimensional interpolation according to the present embodiment, linear interpolation in the X-direction is first performed. Specifically, the correction amounts Z_{(m, j)} and Z_{(m, j+1)} respectively at intersection points P_{(m, j)} and P_{(m, j+1)} are calculated by the following expressions (3) and (4), where: the P_{(m, j)} and P_{(m, j+1)} are respectively intersection points of the straight lines Lⱼ and Lⱼ₊₁ with a straight line that passes through the correction point CP_{(m, n)} and is parallel to the Y axis.

$$\begin{matrix}[ Expression 1 ] & \\ {Z}_{( m , j )} = {Z}_{( i , j )} + ( \frac{{X}_{m} - {X}_{i}}{{X}_{i + 1} - {X}_{i}} ) \times ( {Z}_{( i + 1 , j )} - {Z}_{( i , j )} ) & ( 3 )\end{matrix}$$

$${Z}_{( m , j + 1 )} = {Z}_{( i , j + 1 )} + ( \frac{{X}_{m} - {X}_{i}}{{X}_{i + 1} - {X}_{i}} ) \times ( {Z}_{( i + 1 , j + 1 )} - {Z}_{( i , j + 1 )} ) \qquad ( 4 )$$

Next, the control unit 100 performs linear interpolation in the Y-direction, and calculates the correction amount Z_{(m, n)} at the correction point CP_{(m, n)} by the following expression (5).

$$\begin{matrix}[ Expression 2 ] & \\ {Z}_{( m , n )} = {Z}_{( m , j )} + ( \frac{{Y}_{n} - {Y}_{j}}{{Y}_{j + 1} - {Y}_{j}} ) \times ( {Z}_{( m , j + 1 )} - {Z}_{( m , j )} ) & ( 5 )\end{matrix}$$

Thereby, the correction amount Z_{(m, n)} at the correction point CP_{(m, n)} on the scheduled division line CL₍ₙ₎ can be calculated from the table displacement map. Thus calculating the correction amount Z_{(m, n)} at the correction point CP_{(m, n)} on the scheduled division line CL₍ₙ₎ makes it possible to control the height of the blade 16 according to the Z coordinate Z_{(m, n)} with high accuracy, as illustrated in FIG. 4.

In addition, if the correction point CP_{(m, n)} is outside the grid of the table displacement map; in other words, if there are less than four measurement points surrounding the correction point CP_{(m, n)}, the correction amount Z_{(m, n)} may be calculated by extrapolation using the data of the closest one measurement point to three measurement points.

In the present embodiment, the linear interpolation in the X-direction is performed first, but the linear interpolation in the Y-direction may be performed first. Further, instead of linear interpolation, polynomial interpolation, spline interpolation, or the like may be applied.

### Dicing Method

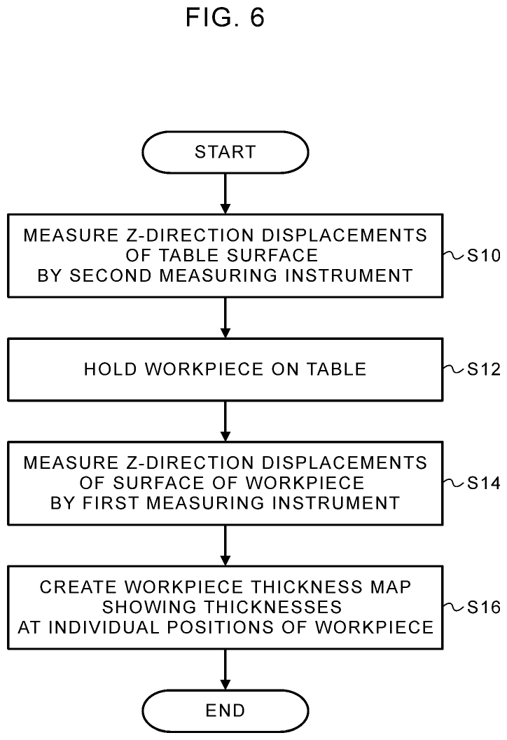

FIG. 6 is a flowchart illustrating a procedure of calculating correction data according to a first embodiment of the present invention.

First, the control unit 100 measures the Z-direction displacement of the surface of the table CT in the Z-direction by the second measuring instruments 20-1 and 20-2, and creates a table displacement maps (z1_smap and z2_smap) (step S10).

Next, while the workpiece W is held on the table CT (step S12), the control unit 100 measures the displacements of the surface of the workpiece W in the Z-direction by the first measuring instrument 18 (step S14). Then, the control unit 100 creates a workpiece thickness map (amm_map) showing the thicknesses at individual positions of the workpiece W (step S16). The table displacement maps (z1_smap and z2_smap) and the workpiece thickness map (amm_map) are stored in the storage device of the control unit 100.

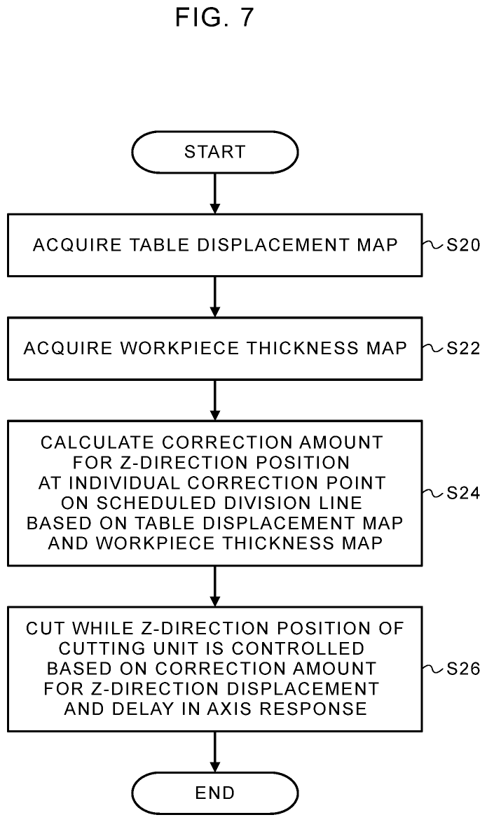

Next, a blade height control method using the table displacement maps (z1_smap and z2_smap) and the workpiece thickness map (amm_map) will be described. FIG. 7 is a flowchart showing the blade height control method.

First, the control unit 100 reads out the table displacement maps (z1_smap and z2_smap) and the workpiece thickness map (amm_map) (steps S20 and S22).

Next, the control unit 100 calculates the correction amount Z_{(i, j)} for each measurement point MP_{(i, j)} based on the table displacement maps (z1_smap and z2_smap) and the workpiece thickness map (amm_map). Then, the control unit 100 calculates the correction amount Z_{(m, n)} at the correction point CP_{(m, n)} on the scheduled division line CL₍ₙ₎ using the correction amount Z_{(i, j)} of the correction data at the measurement points MP_{(i, j)} around the correction point CP_{(m, n)} (step S24: correction amount calculation step). In step S24, the control unit 100 calculates the correction amount Z_{(m, n)} using the expression (3) to the expression (5).

Next, the control unit 100 cuts the workpiece W while controlling the Z-direction positions (heights) of the blades 16-1 and 16-2 based on the correction amount Z_{(m, n)} (step S26). In step S26, at the correction point CP_{(m, n)}, to achieve controlling the blades 16-1 and 16-2 to be positioned at the Z-direction position with the correction amount Z_{(m, n)} being added, the control unit 100 estimates a delay in axis response. Specifically, the Z position is commanded for a certain distance ahead in the traveling direction of each of blades 16-1 and 16-2. Here, the certain distance can be automatically calculated according to the relative speed (cutting speed) between the table CT and each of blades 16-1 and 16-2 at the time of cutting.

The present embodiment makes it possible to achieve controlling the height of the blade 16 in the Z-direction in real time with high accuracy when the table CT, the dicing tape DT, the workpiece W, and the base plate each have a displacement component in the Z-direction.

### First Modification

In the above embodiment, a workpiece thickness map (amm_map) showing the thickness of the workpiece W is created, but the present invention is not limited to this. For example, when the thickness variation of the workpiece W, dicing tape DT and base plate is small, the height of the blade 16 may be controlled using only the table displacement maps (z1_smap and z2_smap) without creating a workpiece thickness map (amm_map).

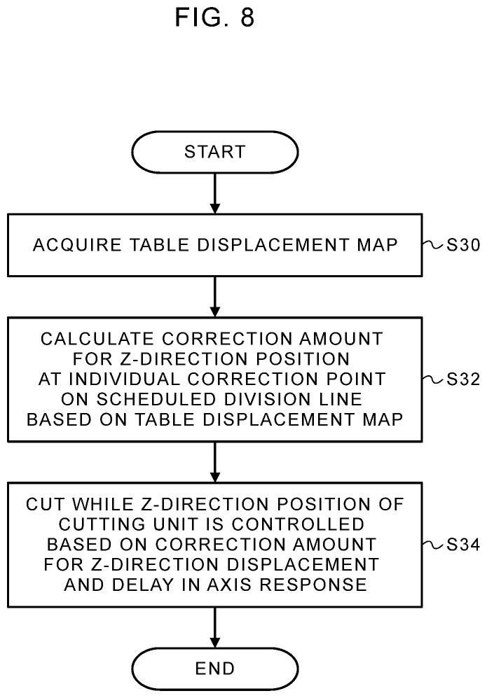

FIG. 8 is a flowchart illustrating a blade height control method according to a first modification.

First, the control unit 100 reads out the table displacement maps (z1_smap and z2_smap) (step S30). Next, the control unit 100 calculates the correction amount Z_{(i, j)} for each measurement point MP_{(i, j)} based on the table displacement maps (z1_smap and z2_smap). Then, the control unit 100 calculates the correction amount Z_{(m, n)} at the correction point CP_{(m, n)} on the scheduled division line CL₍ₙ₎ using the correction amount Z_{(i, j)} of the correction data at the measurement points MP_{(i, j)} around the correction point CP_{(m, n)} (step S32: correction amount calculation step). Next, the control unit 100 cuts the workpiece W while controlling the Z-direction positions (heights) of the blades 16-1 and 16-2 based on the correction amount Z_{(m, n)} (step S34).

This modification makes it possible to control the height of the blade 16 in the Z-direction with a simpler procedure when the thickness variation of the workpiece W, the dicing tape DT and the base plate is smaller than the machining accuracy of the workpiece W.

### Second Modification

In the above embodiment, the dicing device 10 is configured to include an air micrometer as the first measuring instrument 18. However, it may be configured not to include an air micrometer and to create a workpiece thickness map (amm_map) in an external device with respect to the dicing device 10.

### Reference Signs List

10 . . . dicing device, 12 . . . cutting unit, 14 . . . spindle, 16 . . . blade, 18 . . . first measuring instrument, 20 . . . second measuring instrument, CT . . . table, 50 . . . drive unit, 52 . . . table drive unit, 54 . . . pump, 56 . . . regulator, 58 . . . A/E converter, 60 . . . first signal processing unit, 62 . . . nozzle, 64 . . . measuring head, 66 . . . stylus, 68 . . . differential transformer, 70 . . . second signal processing unit, 100 . . . control unit, 102 . . . input unit, 104 . . . display unit

What is claimed is:

1. A dicing device comprising:
a workpiece table for holding a workpiece on a holding surface parallel to an XY plane;
at least one cutting unit each including: a blade for cutting the workpiece held on the workpiece table; and a spindle for rotating the blade around a rotation axis parallel to the XY plane;
an XY-direction drive unit for moving the cutting unit and the workpiece table relatively in a direction parallel to the XY plane;
a Z-direction drive unit for moving the cutting unit in a Z-direction perpendicular to the XY plane;
a first measuring instrument, movably attached together with the cutting unit, for measuring a Z-direction position of a surface of the workpiece held on the holding surface of the workpiece table;
a second measuring instrument for measuring a Z-direction displacement of the holding surface of the workpiece table;
a correction amount calculation unit for calculating, in advance, a correction amount for a Z-direction position of the cutting unit based on a table displacement map showing the Z-direction displacement at each position on the holding surface of the workpiece table and based on the Z-direction position of the surface of the workpiece held on the holding surface of the workpiece table, the Z-direction displacement having been measured in advance by the second measuring instrument, the Z-direction position being measured by the first measuring instrument; and
a control unit for controlling, when the workpiece held on the holding surface of the workpiece table is cut by the blade, the Z-direction drive unit in real time based on the correction amount having been calculated in advance by the correction amount calculation unit.

2. The dicing device according to claim 1, wherein
the at least one cutting unit includes two cutting units,
the first measuring instrument is attached to one of the two cutting units, and
the second measuring instruments are each arranged at the same Z-direction position as a lower end of the blade of each of the two cutting units.

3. The dicing device according to claim 1, wherein
the correction amount calculation unit calculates a workpiece thickness map showing thicknesses of the workpiece at individual positions on the workpiece based on the table displacement map showing the Z-direction displacement at each position on the holding surface of the workpiece table and based on the Z-direction position of the surface of the workpiece, the Z-direction displacement having been measured in advance by the second measuring instrument, the Z-direction position being measured by the first measuring instrument, and calculates the correction amount for the Z-direction position of the cutting unit based on the table displacement map and the workpiece thickness map.

4. The dicing device according to claim 1, wherein
the first measuring instrument includes an air micrometer.

5. The dicing device according to claim 1, wherein
the second measuring instrument includes a differential transformer.

6. The dicing device according to claim 1, wherein
the second measuring instrument is a contact type displacement sensor, and
the second measuring instrument is attached to the cutting unit after the blade is removed therefrom, such that an XY-direction position of an end of a stylus of the second measuring instrument is respectively the same as an XY-position of a lower end position of the blade.

7. A blade height correction method for a dicing device including a workpiece table for holding a workpiece on a holding surface parallel to an XY plane, at least one cutting unit, a first measuring instrument movably attached together with the cutting unit, and a second measuring instrument, the cutting unit including a blade for cutting the workpiece, the cutting unit being movable in a Z-direction perpendicular to the XY plane, the blade height correction method comprising:
a step of acquiring a table displacement map showing a Z-direction displacement at each position on the holding surface of the workpiece table, the Z-direction displacement having been measured by the second measuring instrument;
a step of measuring, by the first measuring instrument, a Z-direction position of a surface of the workpiece held on the holding surface of the workpiece table; and
a correction amount calculating step of calculating, in advance, a correction amount for a Z-direction position of the cutting unit based on the table displacement map and a Z-direction position of the surface of the workpiece held on the holding surface of the workpiece table, the Z-direction position being measured by the first measuring instrument.

8. The blade height correction method according to claim 7, wherein,
in the correction amount calculating step, a workpiece thickness map showing thicknesses of the workpiece at individual positions on the workpiece is calculated based on the table displacement map showing the Z-direction displacement at each position on the holding surface of the workpiece table and based on the Z-direction position of the surface of the workpiece, the Z-direction displacement having been measured in advance by the second measuring instrument, the Z-direction position being measured by the first measuring instrument; and the correction amount for the Z-direction position of the cutting unit is calculated based on the table displacement map and the workpiece thickness map.

9. A workpiece processing method, comprising a step of controlling, based on the correction amount having been calculated in advance by the method according to claim 7, the Z-direction position of the cutting unit in real time when the workpiece held on the holding surface of the workpiece table is cut by the blade.

10. A workpiece processing method, comprising a step of controlling, based on the correction amount having been calculated in advance by the method according to claim 8, the Z-direction position of the cutting unit in real time when the workpiece held on the holding surface of the workpiece table is cut by the blade.
